(19) United States
(12) Patent Application Publication
(10) Pub. No.: US 2021/0218364 A1
(43) Pub. Date: Jul. 15, 2021

(54) REDUCING RADIATED HEAT ON A MULTI-CELL SOLAR PANEL

(71) Applicant: Flex Ltd., Singapore (SG)

(72) Inventor: Mark Philip Lavelle, Vista, CA (US)

(21) Appl. No.: 16/743,481

(22) Filed: Jan. 15, 2020

(51) Int. Cl. H02S 40/22; H02S 30/10; H02S 40/40

(52) U.S. Cl. CPC H02S 40/22; H02S 40/40; H02S 30/10

(57) ABSTRACT

Embodiments of the disclosure a reflective frame of a multicell solar panel to reduce radiant heating on a surface of the solar panel. According to one embodiment, a solar panel mask can comprise a reflective layer comprising a planar sheet of light reflective material and a plurality of cutouts in the reflective layer positioned to expose each of a plurality of solar cells of a solar panel to an incident light source when the solar panel mask is positioned on the solar panel. The plurality of cutouts can form the reflective layer into a reflective frame.

### FIELD OF THE DISCLOSURE

Embodiments of the present disclosure relate generally to methods and systems for multi-cell solar panels and more particularly to a reflective frame of a multicell solar panel to reduce radiant heating on a surface of the solar panel.

### BACKGROUND

A solar panel typically consists of a structural frame containing a number of solar cells. When using solar panels that are composed of several smaller cells, a great amount of heat is produced due to the solar heating of the frame of the panel. This heating can negatively affect the efficiency and longevity of the panel. Hence, there is a need for improved methods and systems for reducing heating on the surface of a solar panel.

### BRIEF SUMMARY

Embodiments of the disclosure a reflective frame of a multicell solar panel to reduce radiant heating on a surface of the solar panel. According to one embodiment, a solar panel mask can comprise a reflective layer comprising a planar sheet of light reflective material and a plurality of cutouts in the reflective layer positioned to expose each of a plurality of solar cells of a solar panel to an incident light source when the solar panel mask is positioned on the solar panel. The plurality of cutouts can form the reflective layer into a reflective frame.

In some cases, the solar panel mask can further comprise an adhesive layer disposed adjacent to the reflective frame on a side of the reflective frame contacting the solar panel when the solar panel mask is installed on the solar panel. In such cases, the adhesive layer may not extend into any of the plurality of cutouts.

The solar panel mask may, in some cases comprise a translucent layer substantially covering each of the plurality of cutouts.

In some cases, the solar panel mask can comprise one or more clamps disposed adjacent to an edge of the reflective frame and the solar panel when the solar panel mask is installed on the solar panel. The one or more clamps can affix the solar panel mask to the solar panel.

The solar panel mask can, in some cases, comprise one or more fastener holes disposed within the reflective frame of the solar panel mask. The one or more fastener holes can align with one or more fastener receptacles in the solar panel when the solar panel mask is installed on the solar panel. One or more fasteners can be disposed within the one or more fastener holes and one or more fastener receptacles and can secure the reflective frame to the solar panel when the solar panel mask is installed on the solar panel. For example, the one or more fasteners can comprise bolts or screws.

In some cases, the solar panel mask can comprise a rectangular bracket adjoining two or more edges of the reflective frame. In such cases, the solar panel can slide into and can be retained by the rectangular bracket when the solar panel mask is installed on the solar panel.

The solar panel mask can, in some cases, comprise one or more latches. Each latch can be disposed along an edge of the solar panel mask, can engage a corresponding edge of the solar panel, and can retain the solar panel mask on the solar panel when the solar panel mask is installed on the solar panel.

In some cases, the solar panel mask can comprise one or more bands. Each band can be affixed to two or more edges of the solar panel mask. Each band can encircle the solar panel and retain the solar panel mask on the solar panel when the solar panel mask is installed on the solar panel. For example, at least one of the one or more bands can comprise an elastic band.

According to another embodiment, a solar panel can comprise a plurality of solar cells and a mask positioned on the solar panel. The mask can comprise a reflective layer comprising a planar sheet of light reflective material and a plurality of cutouts in the reflective layer positioned to expose each of the plurality of solar cells to an incident light source. The plurality of cutouts can form the reflective layer into a reflective frame.

In some cases, the solar panel can further comprise an adhesive layer disposed adjacent to the reflective frame on a side of the reflective frame contacting the solar panel when the solar panel mask is installed on the solar panel. In such cases, the adhesive layer may not extend into any of the plurality of cutouts.

The solar panel may, in some cases comprise a translucent layer substantially covering each of the plurality of cutouts.

In some cases, the solar panel can comprise one or more clamps disposed adjacent to an edge of the reflective frame and the solar panel when the solar panel mask is installed on the solar panel. The one or more clamps can affix the solar panel mask to the solar panel.

The solar panel can, in some cases, comprise one or more fastener holes disposed within the reflective frame of the solar panel mask. The one or more fastener holes can align with one or more fastener receptacles in the solar panel when the solar panel mask is installed on the solar panel. One or more fasteners can be disposed within the one or more fastener holes and one or more fastener receptacles and can secure the reflective frame to the solar panel when the solar panel mask is installed on the solar panel. For example, the one or more fasteners can comprise bolts or screws.

In some cases, the solar panel can comprise a rectangular bracket adjoining two or more edges of the reflective frame. In such cases, the solar panel can slide into and can be retained by the rectangular bracket when the solar panel mask is installed on the solar panel.

The solar panel can, in some cases, comprise one or more latches. Each latch can be disposed along an edge of the solar panel mask, can engage a corresponding edge of the solar panel, and can retain the solar panel mask on the solar panel when the solar panel mask is installed on the solar panel.

In some cases, the solar panel can comprise one or more bands. Each band can be affixed to two or more edges of the solar panel mask. Each band can encircle the solar panel and retain the solar panel mask on the solar panel when the solar panel mask is installed on the solar panel. For example, at least one of the one or more bands can comprise an elastic band.

### BRIEF DESCRIPTION OF THE DRAWINGS

FIG. 1 illustrates a view of a solar panel as may be used with embodiments of the present disclosure.

FIG. 2 illustrates a view of a solar panel mask according to one embodiment of the present disclosure.

FIG. 3 illustrates a view of an adhesive layer according to one embodiment of the present disclosure.

FIG. 4 illustrates a view of an assembled solar panel with solar panel mask according to one embodiment of the present disclosure.

FIG. 5 illustrates an exploded view of a solar panel, adhesive layer, and solar panel mask assembly according to one embodiment of the present disclosure.

FIG. 6 illustrates an exploded view of a solar panel and solar panel mask assembly according to an alternative embodiment of the present disclosure.

FIG. 7 illustrates an exploded view of a solar panel and solar panel mask assembly according to another alternative embodiment of the present disclosure.

FIG. 8 illustrates an exploded view of a solar panel and solar panel mask assembly according to yet another alternative embodiment of the present disclosure.

FIG. 9 illustrates an exploded view of a solar panel and solar panel mask assembly according to another alternative embodiment of the present disclosure.

FIG. 10 illustrates an exploded view of a solar panel and solar panel mask assembly according to still another alternative embodiment of the present disclosure.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the second reference label.

### DETAILED DESCRIPTION

In the following description, for the purposes of explanation, numerous specific details are set forth in order to provide a thorough understanding of various embodiments disclosed herein. It will be apparent, however, to one skilled in the art that various embodiments of the present disclosure may be practiced without some of these specific details. The ensuing description provides exemplary embodiments only, and is not intended to limit the scope or applicability of the disclosure. Furthermore, to avoid unnecessarily obscuring the present disclosure, the preceding description omits a number of known structures and devices. This omission is not to be construed as a limitation of the scopes of the claims. Rather, the ensuing description of the exemplary embodiments will provide those skilled in the art with an enabling description for implementing an exemplary embodiment. It should however be appreciated that the present disclosure may be practiced in a variety of ways beyond the specific detail set forth herein.

As used herein, the phrases “at least one,” “one or more,” “or,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C,” “A, B, and/or C,” and “A, B, or C” means A alone, B alone, C alone, A and B together, A and C together, B and C together, or A, B and C together.

The term “a” or “an” entity refers to one or more of that entity. As such, the terms “a” (or “an”), “one or more” and “at least one” can be used interchangeably herein. It is also to be noted that the terms “comprising,” “including,” and “having” can be used interchangeably.

The term “automatic” and variations thereof, as used herein, refers to any process or operation done without material human input when the process or operation is performed. However, a process or operation can be automatic, even though performance of the process or operation uses material or immaterial human input, if the input is received before performance of the process or operation. Human input is deemed to be material if such input influences how the process or operation will be performed. Human input that consents to the performance of the process or operation is not deemed to be “material.”

It shall be understood that the term “means” as used herein shall be given its broadest possible interpretation in accordance with 35 U.S.C., Section 112, Paragraph 6. Accordingly, a claim incorporating the term “means” shall cover all structures, materials, or acts set forth herein, and all of the equivalents thereof. Further, the structures, materials or acts and the equivalents thereof shall include all those described in the summary of the disclosure, brief description of the drawings, detailed description, abstract, and claims themselves.

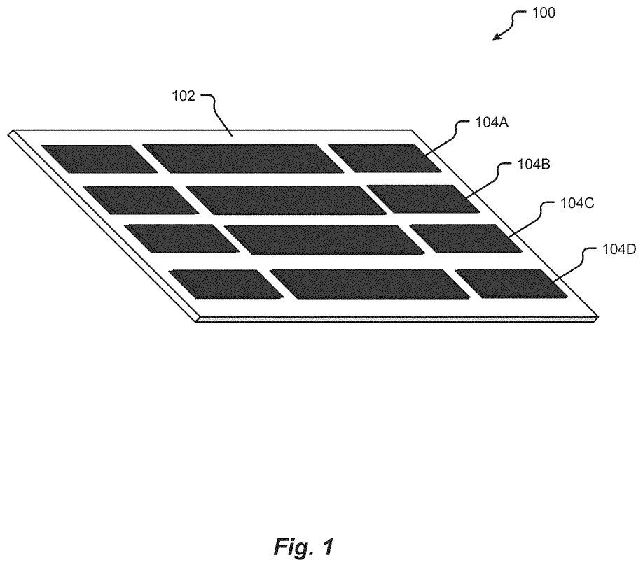

FIG. 1 illustrates a view of a solar panel as may be used with embodiments of the present disclosure. As illustrated in this example, and as known in the art, a solar panel 100 can comprise a structural frame 105 and a plurality of solar cells 104A-104D mounted on and secured by the structural frame 102. It should be noted and understood that the solar panel 100 illustrated here is provided by way of example only and is not intended to limit the scope of the present disclosure. For example, size and shape of the solar panel 100, the number and arrangement of the plurality of cells 104A-104D, etc. can vary significantly depending on the exact implementation. Additionally, it should be understood that the following examples of various embodiments can be adapted depending upon the size, shape, arrangement, etc. of the solar panel 100 and such adaptations are also considered to be within the scope of the present disclosure.

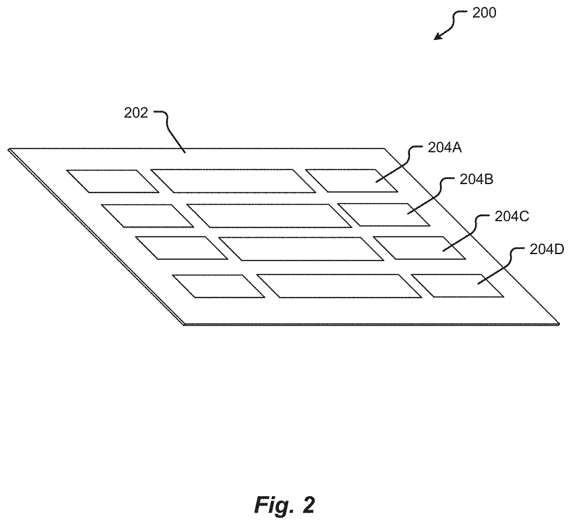

FIG. 2 illustrates a view of a solar panel mask according to one embodiment of the present disclosure. As illustrated in this example, a solar panel mask 200 can comprise a reflective layer 202 comprising a planar sheet of light reflective material. A plurality of cutouts 204A-204D can be made in the reflective layer 202 positioned to expose each of a plurality of solar cells 104A-104D of a solar panel 100 to an incident light source when the solar panel mask 200 is positioned on the solar panel 100. The plurality of cutouts 204A-204D forming the reflective layer 202 into a reflective frame matching the supporting structure 102 of the solar panel without covering the solar cells 104A-104D.

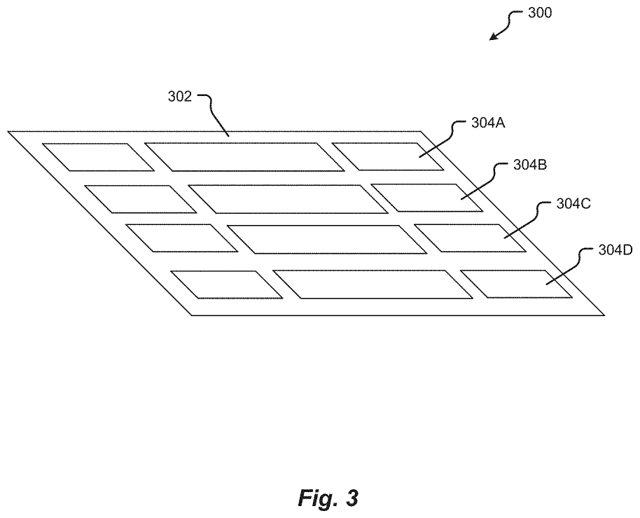

FIG. 3 illustrates a view of an adhesive layer according to one embodiment of the present disclosure. As illustrated in this example, the solar panel mask 200 can further comprise an adhesive layer 300, e.g., double-sided tape, glue, etc, that can be disposed adjacent to the reflective frame on a side of the reflective frame contacting the solar panel 100 when the solar panel mask 200 is installed on the solar panel 100. According to one embodiment, the adhesive layer 300 does not extend into any of the plurality of cutouts 204A-204D or cover any of the solar cells 104A-104D when the solar panel mask 200 is installed on the solar panel 100. According to another embodiment, the adhesive layer may comprise a translucent layer substantially covering each of the plurality of cutouts 204A-204D and solar cells 104A-104D when the solar panel mask 200 is installed on the solar panel 100 with an adhesive portion 302, e.g., double-sided tape, glue, etc., substantially matching the solar panel mask 200 and supporting structure 102 of the solar panel 100.

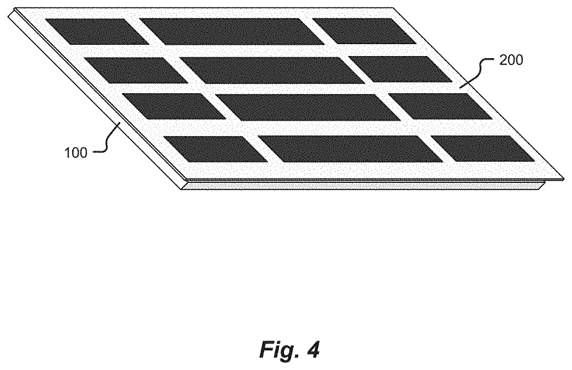

FIG. 4 illustrates a view of an assembled solar panel with solar panel mask according to one embodiment of the present disclosure. As illustrated in this example, a solar panel mask 200 can comprise a reflective layer 202 comprising a planar sheet of light reflective material and a plurality of cutouts 204A-204D in the reflective layer 202 positioned to expose each of a plurality of solar cells 104A-104D of a solar panel 100 to an incident light source when the solar panel mask 200 is positioned on the solar panel 100. The plurality of cutouts 204A-204D forming the reflective layer 202 into a reflective frame.

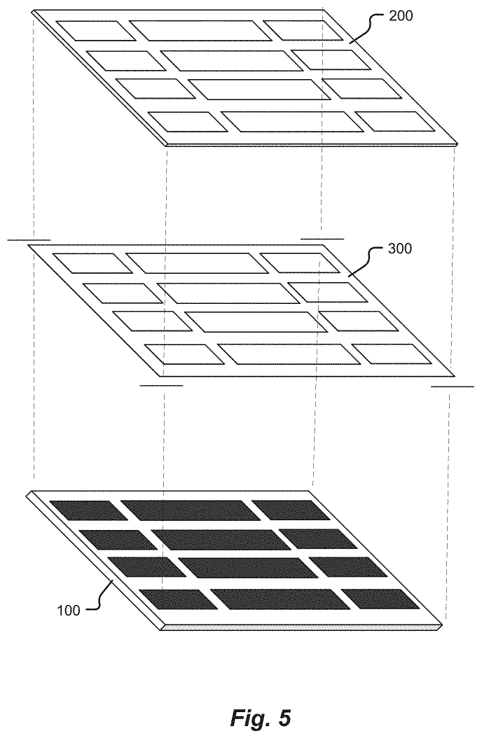

FIG. 5 illustrates an exploded view of a solar panel, adhesive layer, and solar panel mask assembly according to one embodiment of the present disclosure. As illustrated in this example, a solar panel mask 200 can comprise a reflective layer 202 comprising a planar sheet of light reflective material and a plurality of cutouts 204A-204D in the reflective layer 202 positioned to expose each of a plurality of solar cells 104A-104D of a solar panel 100 to an incident light source when the solar panel mask 200 is positioned on the solar panel 100. The plurality of cutouts 204A-204D forming the reflective layer 202 into a reflective frame.

The solar panel mask 200 can further comprise an adhesive layer 300 disposed adjacent to the reflective frame on a side of the reflective frame contacting the solar panel 100 when the solar panel mask 200 is installed on the solar panel 100. According to one embodiment, the adhesive layer 300 does not extend into any of the plurality of cutouts 204A-204D. In some embodiment, the adhesive layer 300 can comprise a translucent layer substantially covering each of the plurality of cutouts 204A-204D with adhesive applied to an area not extending into any of the plurality of cutouts 204A-204D.

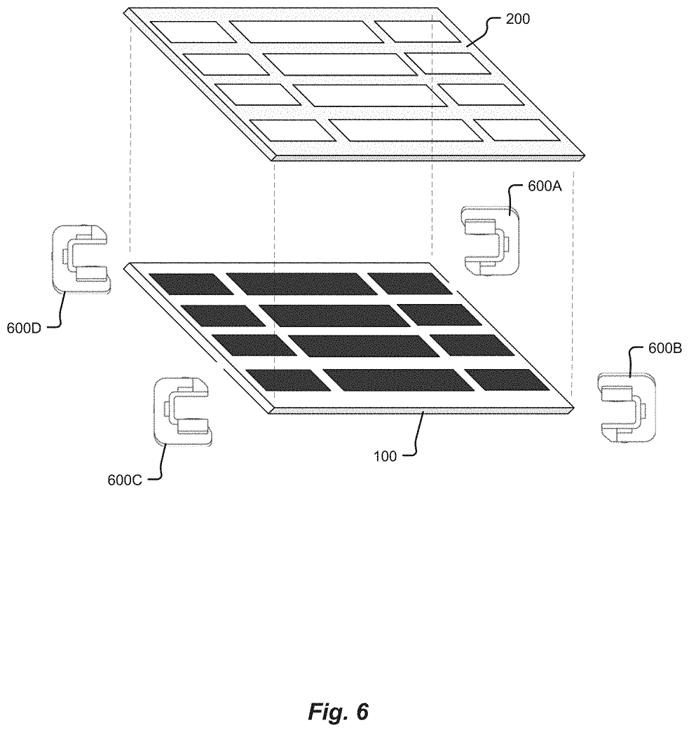

FIG. 6 illustrates an exploded view of a solar panel 100 and solar panel mask assembly according to an alternative embodiment of the present disclosure. As illustrated in this example, the solar panel 100 and solar panel mask 200 assembly can further comprise one or more clamps 600A-600D. The clamps 600A-600D can be disposed adjacent to an edge of the reflective frame of the solar panel mask 200 and the solar panel 100 when the solar panel mask 200 is installed on the solar panel 100, the one or more clamps 600A-600D affixing the solar panel mask 200 to the solar panel 100.

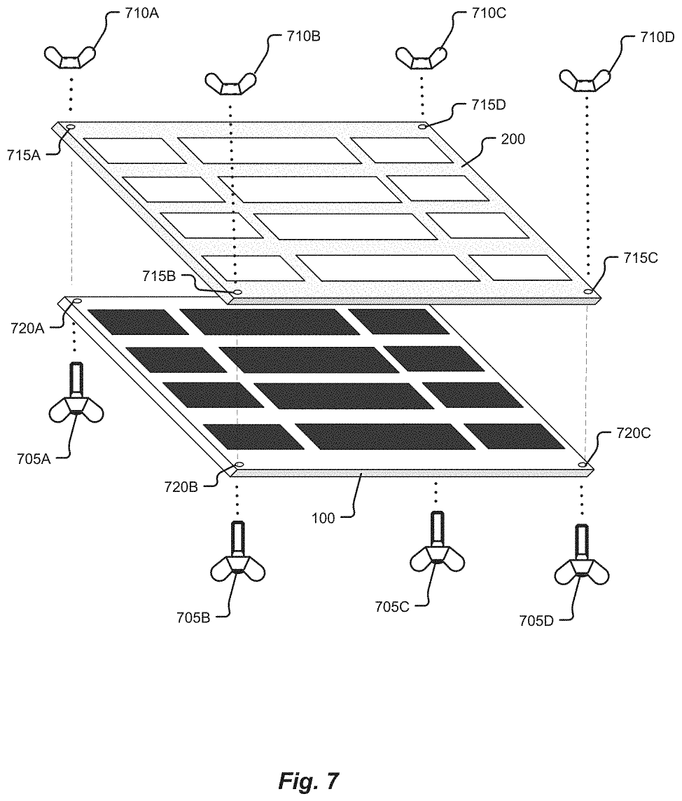

FIG. 7 illustrates an exploded view of a solar panel and solar panel mask assembly according to another alternative embodiment of the present disclosure. As illustrated in this example, the solar panel 100 and solar panel mask 200 assembly can further comprise one or more fastener holes 715A-715D disposed within the reflective frame of the solar panel mask 200. The one or more fastener holes 715A-715D can align with one or more fastener receptacles 720A-720C in the solar panel 100 when the solar panel mask 200 is installed on the solar panel 100. One or more fasteners 705A-705D and 710A-710D disposed within the one or more fastener holes 715A-715D and one or more fastener receptacles 720A-720C and securing the reflective frame to the solar panel 100 when the solar panel mask 200 is installed on the solar panel 100. For example, the one or more fasteners 705A-705D and 710A-710D can comprise bolts or screws.

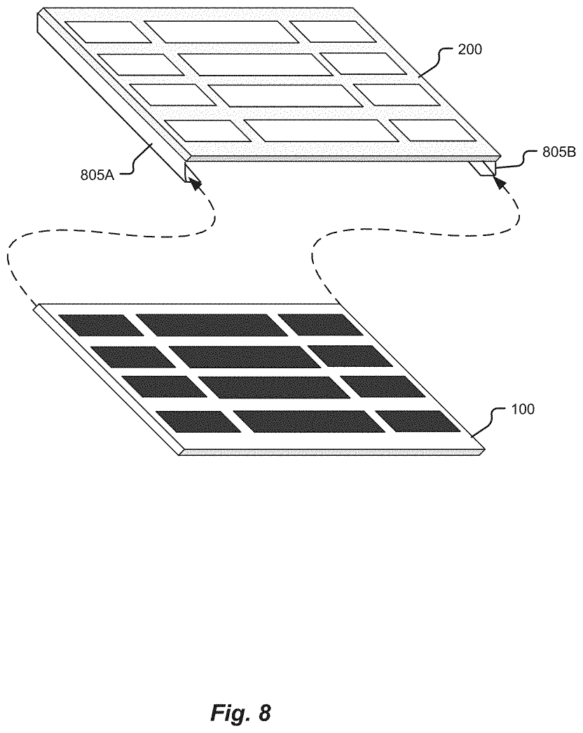

FIG. 8 illustrates an exploded view of a solar panel and solar panel mask assembly according to yet another alternative embodiment of the present disclosure. As illustrated in this example, the solar panel 100 and solar panel mask 200 assembly can further comprise a rectangular bracket 805A and 805B adjoining two or more edges of the reflective frame. The solar panel 100 can slide into and is retained by the rectangular bracket 805A and 805B when the solar panel mask 200 is installed on the solar panel 100.

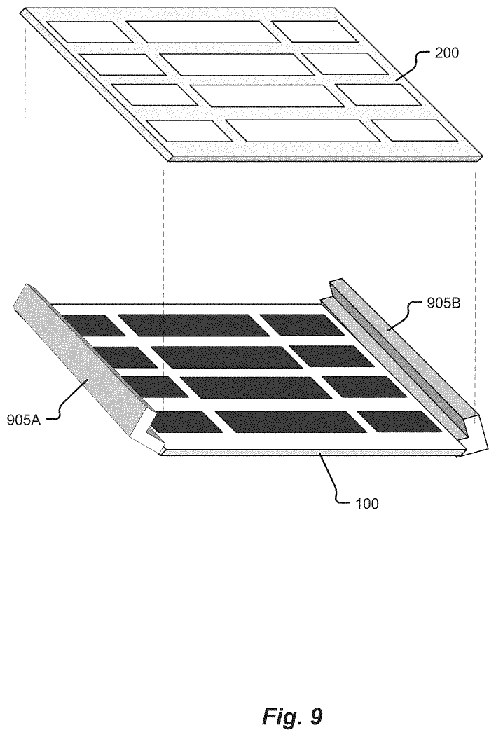

FIG. 9 illustrates an exploded view of a solar panel and solar panel mask assembly according to another alternative embodiment of the present disclosure. As illustrated in this example, the solar panel 100 and solar panel mask 200 assembly can further comprise one or more latches 905A and 905B. Each latch can be disposed along an edge of the solar panel mask 200 and can engage a corresponding edge of the solar panel 100 and retain the solar panel mask 200 on the solar panel 100, e.g., by springs (not visible here) within the latches, when the solar panel mask 200 is installed on the solar panel 100.

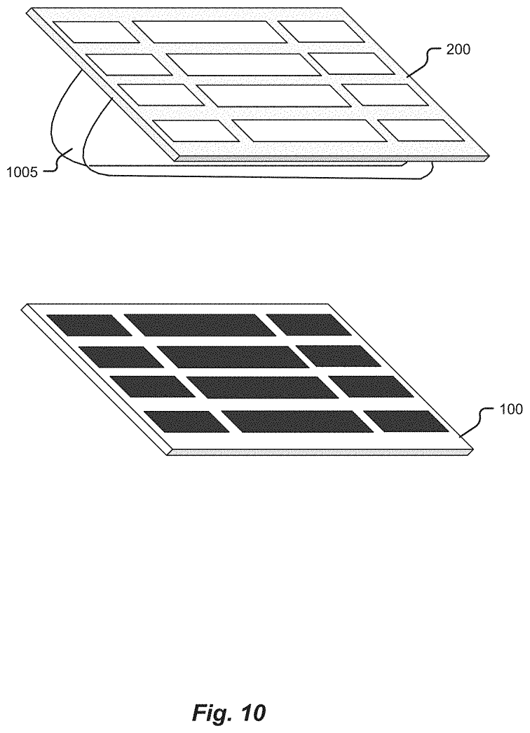

FIG. 10 illustrates an exploded view of a solar panel and solar panel mask assembly according to still another alternative embodiment of the present disclosure. As illustrated in this example, the solar panel 100 and solar panel mask 200 assembly can further comprise one or more bands 1005. Each band 1005 can be affixed to two or more edges of the solar panel mask 200. Each band 1005 can encircle the solar panel 100 and retain the solar panel mask 200 on the solar panel 100 when the solar panel mask 200 is installed on the solar panel 100. For example, the one or more bands 1005 can comprise an elastic band. In other cases, the bands 1005 can comprise a fabric band secured with hook and loop fasteners, snaps, or other fasteners.

The present disclosure, in various aspects, embodiments, and/or configurations, includes components, methods, processes, systems, and/or apparatus substantially as depicted and described herein, including various aspects, embodiments, configurations embodiments, sub-combinations, and/or subsets thereof. Those of skill in the art will understand how to make and use the disclosed aspects, embodiments, and/or configurations after understanding the present disclosure. The present disclosure, in various aspects, embodiments, and/or configurations, includes providing devices and processes in the absence of items not depicted and/or described herein or in various aspects, embodiments, and/or configurations hereof, including in the absence of such items as may have been used in previous devices or processes, e.g., for improving performance, achieving ease and\or reducing cost of implementation.

The foregoing discussion has been presented for purposes of illustration and description. The foregoing is not intended to limit the disclosure to the form or forms disclosed herein. In the foregoing Detailed Description for example, various features of the disclosure are grouped together in one or more aspects, embodiments, and/or configurations for the purpose of streamlining the disclosure. The features of the aspects, embodiments, and/or configurations of the disclosure may be combined in alternate aspects, embodiments, and/or configurations other than those discussed above. This method of disclosure is not to be interpreted as reflecting an intention that the claims require more features than are expressly recited in each claim. Rather, as the following claims reflect, inventive aspects lie in less than all features of a single foregoing disclosed aspect, embodiment, and/or configuration. Thus, the following claims are hereby incorporated into this Detailed Description, with each claim standing on its own as a separate preferred embodiment of the disclosure.

Moreover, though the description has included description of one or more aspects, embodiments, and/or configurations and certain variations and modifications, other variations, combinations, and modifications are within the scope of the disclosure, e.g., as may be within the skill and knowledge of those in the art, after understanding the present disclosure. It is intended to obtain rights which include alternative aspects, embodiments, and/or configurations to the extent permitted, including alternate, interchangeable and/or equivalent structures, functions, ranges or steps to those claimed, whether or not such alternate, interchangeable and/or equivalent structures, functions, ranges or steps are disclosed herein, and without intending to publicly dedicate any patentable subject matter.

What is claimed is:

1. A solar panel mask, the mask comprising:
a reflective layer comprising a planar sheet of light reflective material; and
a plurality of cutouts in the reflective layer positioned to expose each of a plurality of solar cells of a solar panel to an incident light source when the solar panel mask is positioned on the solar panel, the plurality of cutouts forming the reflective layer into a reflective frame.

2. The solar panel mask of claim 1, further comprising:
an adhesive layer disposed adjacent to the reflective frame on a side of the reflective frame contacting the solar panel when the solar panel mask is installed on the solar panel and wherein the adhesive layer does not extend into any of the plurality of cutouts.

3. The solar panel mask of claim 1, further comprising a translucent layer substantially covering each of the plurality of cutouts.

4. The solar panel mask of claim 1, further comprising:
one or more clamps disposed adjacent to an edge of the reflective frame and the solar panel when the solar panel mask is installed on the solar panel, the one or more clamps affixing the solar panel mask to the solar panel.

5. The solar panel mask of claim 1, further comprising:
one or more fastener holes disposed within the reflective frame of the solar panel mask, the one or more fastener holes aligning with one or more fastener receptacles in the solar panel when the solar panel mask is installed on the solar panel; and
one or more fasteners disposed within the one or more fastener holes and one or more fastener receptacles and securing the reflective frame to the solar panel when the solar panel mask is installed on the solar panel.

6. The solar panel mask of claim 5, wherein the one or more fasteners comprise bolts or screws.

7. The solar panel mask of claim 1, further comprising:
a rectangular bracket adjoining two or more edges of the reflective frame, wherein the solar panel slides into and is retained by the rectangular bracket when the solar panel mask is installed on the solar panel.

8. The solar panel mask of claim 1, further comprising one or more latches, each latch disposed along an edge of the solar panel mask and engaging a corresponding edge of the solar panel and retaining the solar panel mask on the solar panel when the solar panel mask is installed on the solar panel.

9. The solar panel mask of claim 1, further comprising one or more bands, each band affixed to two or more edges of the solar panel mask, wherein each band encircles the solar panel and retains the solar panel mask on the solar panel when the solar panel mask is installed on the solar panel.

10. The solar panel mask of claim 9, wherein at least one of the one or more bands comprises an elastic band.

11. A solar panel comprising:
a plurality of solar cells; and
a mask positioned on the solar panel, the mask comprising a reflective layer comprising a planar sheet of light reflective material and a plurality of cutouts in the reflective layer positioned to expose each of the plurality of solar cells to an incident light source, the plurality of cutouts forming the reflective layer into a reflective frame.

12. The solar panel of claim 11, further comprising:
an adhesive layer disposed adjacent to the reflective frame on a side of the reflective frame contacting the solar panel when the solar panel mask is installed on the solar panel and wherein the adhesive layer does not extend into any of the plurality of cutouts.

13. The solar panel of claim 11, further comprising a translucent layer substantially covering each of the plurality of cutouts.

14. The solar panel of claim 11, further comprising:
one or more clamps disposed adjacent to an edge of the reflective frame and the solar panel when the solar panel mask is installed on the solar panel, the one or more clamps affixing the solar panel mask to the solar panel.

15. The solar panel of claim 11, further comprising:
one or more fastener holes disposed within the reflective frame of the solar panel mask, the one or more fastener holes aligning with one or more fastener receptacles in the solar panel when the solar panel mask is installed on the solar panel; and
one or more fasteners disposed within the one or more fastener holes and one or more fastener receptacles and securing the reflective frame to the solar panel when the solar panel mask is installed on the solar panel.

16. The solar panel of claim 15, wherein the one or more fasteners comprise bolts or screws.

17. The solar panel of claim 11, further comprising:
a rectangular bracket adjoining two or more edges of the reflective frame, wherein the solar panel slides into and is retained by the rectangular bracket when the solar panel mask is installed on the solar panel.

18. The solar panel of claim 11, further comprising one or more latches, each latch disposed along an edge of the solar panel mask and engaging a corresponding edge of the solar panel and retaining the solar panel mask on the solar panel when the solar panel mask is installed on the solar panel.

19. The solar panel of claim 11, further comprising one or more bands, each band affixed to two or more edges of the solar panel mask, wherein each band encircles the solar panel and retains the solar panel mask on the solar panel when the solar panel mask is installed on the solar panel.

20. The solar panel of claim 19, wherein at least one of the one or more bands comprises an elastic band.
